(19) United States
(12) Patent Application Publication
(10) Pub. No.: US 2017/0012017 A1
(43) Pub. Date: Jan. 12, 2017

(54) ASSEMBLY COMPRISING TWO ELEMENTS OF DIFFERENT THERMAL EXPANSION COEFFICIENTS AND A SINTERED JOINT OF HETEROGENEOUS DENSITY AND PROCESS FOR MANUFACTURING THE ASSEMBLY

(71) Applicant: COMMISSARIAT A L'ENERGIE ATOMIQUE ET AUX ENERGIES ALTERNATIVES, PARIS (FR)

(72) Inventors: Rabih KHAZAKA, LA TRONCHE (FR); Benoît THOLLIN, MONTBONNOT ST MARTIN (FR)

(21) Appl. No.: 15/205,273

(22) Filed: Jul. 8, 2016

(30) Foreign Application Priority Data
Jul. 10, 2015 (FR) 1556573

(51) Int. Cl. H01L 23/00; H01L 23/373; B22F 7/06

(52) U.S. Cl. CPC H01L 24/32; B22F 7/064; H01L 24/83; H01L 23/3735; H01L 2924/1203; H01L 2924/10253; H01L 2924/15787; H01L 2924/05032; H01L 2924/05042; H01L 2924/05432; H01L 2224/29147; H01L 2224/29499; H01L 2224/29139; H01L 2224/29144; H01L 2224/32225; H01L 2224/8384; H01L 2224/2732; H01L 2224/83192

(57) ABSTRACT

An assembly comprises a first element having a first thermal expansion coefficient, a second element having a second thermal expansion coefficient and at least one joint connecting the first element and second element, wherein the joint is heterogeneous and includes a stack of at least one first elementary joint of first density and of a second elementary joint of second density, the first and second densities being different. A process for manufacturing an assembly according to the invention is provided.

The field of the invention is that of techniques for joining two elements via sintered joints and especially that of joining components to substrates, for example allowing a semiconductor chip to be bonded to a metallized substrate with or without noble metals, the elements advantageously being intended for high-temperature (above 200° C.) and high-power-density applications.

As is known, to form electronic components semiconductor elements must be attached to substrates. Solders based on lead (Pb—Sn, Pb—Sn—Ag) and on tin (Sn—Ag, Sn—Ag—Cu) are among the most used in the field of electronics. However, European regulations forbid the use of Pb because of its environmental toxicity. Solders based on tin (Sn) are limited to low temperatures (below 200° C.) and are unsuitable for the temperatures targeted by wide bandgap semiconductors such as silicon carbide SiC or gallium nitride GaN.

Other high-temperature solders do exist. They are either based on gold (Au) making them very expensive, or have a high melting point (above 500° C.) incompatible with semiconductors.

Solders based on Au such as the alloys AuSn, AuGe and AuSi have high Young's moduli with respect to lead-based solders, this leading to the generation of very high strains in the joined components and, in certain cases, to the breakage of components.

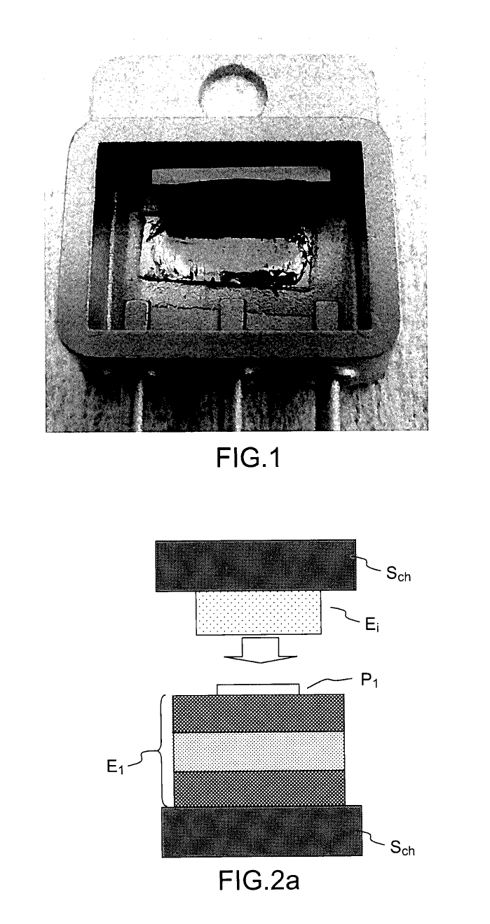

An example of this problem is illustrated in FIG. 1, which shows debonding of a GaN-on-Si (1 mm Si) component following AuSn soldering at 300° C. in a package with a Cu base (Ni/Au finish).

Furthermore, solders have relatively low thermal conductivities (of about 40 W/mK) in addition to exhibiting reliability problems when stored at high temperatures (creation of fragile intermetallics and Kirkendall voids: the diffusion of material in one direction leads voids (vacancies) to diffuse in the other, this possibly causing a deformation of the material) or when subjected to thermal cycling (propagation of cracks in the joint).

To avoid the use of solders, other technologies such as the sintering of metal micro- and nano-particles and transient liquid phase (TLP) bonding, the latter achieving a bond by phase diffusion, are increasingly being used.

The sintering of metal microparticles has been the subject of various studies such as that of Zhang et al., “Pressure-Assisted Low-Temperature Sintering of Silver Paste as an Alternative Die-Attach Solution to Solder reflow”, IEEE Transactions on Electronics Packaging Manufacturing, vol. 25, no. 4, October, 2002 (pp 279-283). A paste containing Ag particles of a plurality of μm diameter and requiring very high sintering temperatures (600° C.) is proposed therein. In order to allow this temperature to be decreased to values more compatible with electronic components, pressures of a few tens of MPa are required, making this joining process very complicated (above all if a plurality of components having different thicknesses are to be joined) and incompatible with components sensitive to high pressures.

It is possible to decrease sintering pressure and temperature by using metal particles of nanoscale sizes. It is preferable for the paste to contain a dispersant in order to prevent the nanoparticles from agglomerating. A polymer binder is also added to the dispersant and to the nanoparticles in order to ensure the end-product takes the form of a paste (i.e. a pasty solution) and to limit the appearance of cracks during drying. A solvent allows different viscosities suitable for various deposition techniques (dispensing, i.e. deposition using a dispensing pen, and screen printing) to be obtained. The development of this type of paste containing nanoscale particles is the subject of a patent by Lu et al. “Nanoscale metal paste for interconnect and method of use”, U.S. Pat. No. 8,257,795 B2. This type of paste, since it requires no pressure during the sintering, is compatible with finishing layers made of Ag or of Au (noble materials that allow the adhesion of the interconnect to be improved).

The sintering process of pastes of metal nanoparticles plays an important role in the density of the joint and therefore in its physical properties. The process-density-mechanical properties relationship has especially been the subject of a number of research studies such as that of Knoerr et al. “Power semiconductor joining through sintering of silver nanoparticles: Evaluation of influence of parameters time, temperature and pressure on density-strength and reliability”, International Conference on Integrated Power Electronics Systems CIPS, Mar. 16-18. 2010, Nuremberg, Germany, and that of Caccuri et al. “Mechanical Properties of Sintered Ag as a New Material for Die Bonding: Influence of the Density”, Journal of Electronic Materials, Vol. 43, No. 12, 2014.

In this context, the Applicant has sought to exploit the latitude offered in terms of density by sintering processes to provide a joining solution allowing a single heterogeneous joint combining various density properties, inducing different controllable physical properties and allowing thermomechanical strains between two elements having different thermal expansion coefficients, for example a semiconductor device and a substrate, to be better absorbed during thermal cycles. By virtue of the solution proposed in the present invention, it is also possible to improve the adhesion of a pressure-sensitive component to a substrate requiring a high pressure by carrying out multi-steps of sintering.

More precisely, one subject of the present invention is an assembly comprising a first element having a first thermal expansion coefficient, a second element having a second thermal expansion coefficient and at least one joint connecting said first element and said second element, characterized in that said joint is heterogeneous and includes a stack of at least one first elementary joint of first density and of a second elementary joint of second density, said first and second densities being different.

The heterogeneous joint thus comprises a first elementary joint of first density having an interface with the second elementary joint of second density.

According to variants of the invention, one of the elements comprises a semiconductor component, possibly for example a silicon diode.

According to variants of the invention, said heterogeneous joint is metallic.

According to variants of the invention, the first element and/or the second element have/has a metallic surface attached to said joint.

According to variants of the invention, one of the two elements is a substrate, possibly a direct bonded copper (DBC) substrate corresponding to a plate, possibly made of Al₂O₃ or Si₃N₄ or AlN, and including at least one metallic layer on one of its faces. It may be a question of a copper film bonded directly to a ceramic plate.

This type of substrate is particularly advantageous in the context of power components having to resist high temperatures.

According to variants of the invention, the first element and the second element comprise a finishing layer intended to make contact with one of the elementary joints.

According to variants of the invention, the thickness of the finishing layer is of the order of one nanometer or one micron (and thus may vary from a few nanometers to as much as one micron or more).

According to variants of the invention, the first elementary joint and the second elementary joint include nanoparticles.

According to variants of the invention, the first elementary joint includes microparticles or nanoparticles, the second elementary joint including nanoparticles (this may be particularly advantageous in the case of pressure-sensitive semiconductor components).

According to variants of the invention, at least one of the first and/or second elements have/has a surface made of copper, possibly a finishing layer.

According to variants of the invention, the first elementary joint is silver-based, the second elementary joint also being silver-based.

According to variants of the invention, the first elementary joint is copper-based, the second elementary joint also being copper-based.

According to variants of the invention, the first elementary joint is gold-based, the second elementary joint also being gold-based.

According to variants of the invention, the first elementary joint is based on silver and copper, the second elementary joint also being based on silver and copper.

According to variants of the invention, the first density is about 90% with respect to the bulk metal, which is possibly silver, the second density being about 60% relative to the bulk metal, which is possibly silver.

Another subject of the invention is a process for manufacturing an assembly comprising a heterogeneous joint and two elements of different thermal expansion coefficients, comprising the following steps:
depositing a first paste or a first film on the surface of the first element;
a first sintering operation under first temperature and pressure conditions so as to produce a first elementary joint of first density;
depositing a second paste or a second film on the surface of said first elementary joint;
a second sintering operation under second temperature and pressure conditions so as to define a second elementary joint of second density different from said first density on the surface of the first elementary joint in order to form said heterogeneous joint;
applying the second element.

According to variants of the invention, the second sintering operation is carried out under lower temperature and/or lower pressure conditions than those of the first sintering operation.

According to variants of the invention, the first sintering operation is carried out while applying an intermediate part to said deposited first paste or to said first film, which does not adhere to said first paste or said first film. This intermediate part may be a glass plate or an element made of polytetrafluoroethylene (PTFE), commonly called Teflon®, or an element made of ceramic, or an element made of aluminum, or an element made of diamond, or an element made of sapphire, or an element made of silicon, or an element made of silicon carbide.

According to variants of the invention, the second sintering operation is carried out while applying the second element to the second paste or to the second film.

According to variants of the invention, the process comprises a step of drying said first paste and/or a step of drying said second paste. This step may allow better controlled joint thicknesses to be obtained for the pressure sintering (the conditions and time depending on the evaporation temperature of the binder and solvent contained in the paste).

According to variants of the invention, the first and/or second paste are/is metallic or the first film and/or the second film are/is metallic.

According to variants of the invention, the first and second pastes are metallic.

According to variants of the invention, the first paste and/or the second paste are/is deposited by screen printing.

According to variants of the invention, the first and second pastes are deposited by screen printing with the same type of sintering paste, the thickness of the deposited first paste possibly being larger than the thickness of the deposited second paste. The same-type paste may be a sintering paste requiring the application of a pressure, the second deposition possibly being carried out in order to obtain a thickness small enough, possibly typically smaller than a few tens of microns (30 microns for example), to obviate the need for a drying step whereas, generally, such a step is necessary because binders need to be removed from this type of sintering paste during the production of the assembly. Typically, it may be a question of a paste based on silver microparticles (what are called pressureless sintering pastes possibly being based on silver nanoparticles).

According to variants of the invention, the first paste and/or the second paste are/is deposited using a dispensing pen.

According to variants of the invention, the first paste and/or second paste are/is deposited by direct imprinting.

According to variants of the invention, the first element having a copper surface, the first paste is silver-based and the second paste is also silver-based.

According to variants of the invention, the first and second paste comprise/comprises nanoparticles and may comprise a dispersant and/or a binder and/or a solvent.

According to variants of the process for manufacturing an assembly comprising a heterogeneous joint according to the invention, the first and/or second paste comprise/comprises metal nanoparticles.

According to variants of the process for manufacturing an assembly comprising a heterogeneous joint according to the invention, the first element is a substrate and the second element is a semiconductor chip.

The joint of heterogeneous density proposed in the present patent application may also allow a good adhesion to be ensured to “non-noble” metals (Cu or Ni) or other substrates generally requiring the presence of a high pressure to ensure a good adhesion (better adhesion due to the plastic deformation of the substrate and the interlocking mechanism, for example with a shear stiffness higher than 10 MPa, without needing to apply a pressure to the chips during mounting, as will be explained below in the detailed description of the present patent application.

The invention will be better understood and other advantages will become apparent on reading the following nonlimiting description, which is given with reference to the appended figures, in which:

FIG. 1 illustrates debonding of a GaN-on-Si (1 mm of Si) component following AuSn soldering at 300° C. in a package with a Cu base (Ni/Au finish);

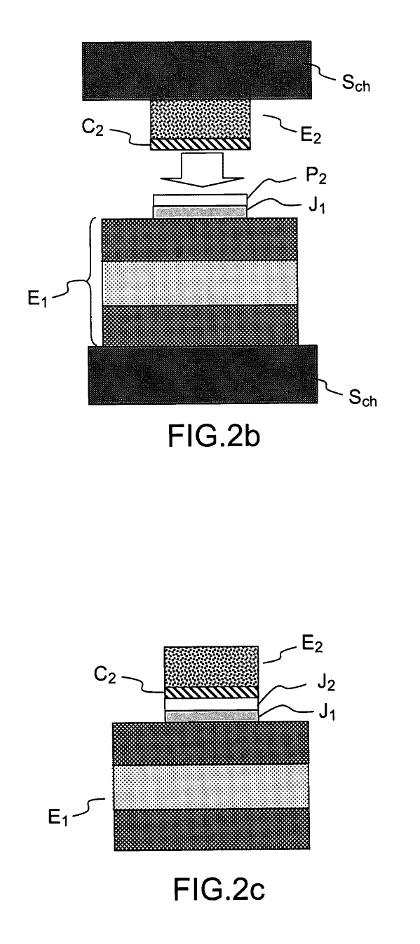

FIGS. 2a to 2c illustrate the main steps of a process for producing an assembly according to the invention;

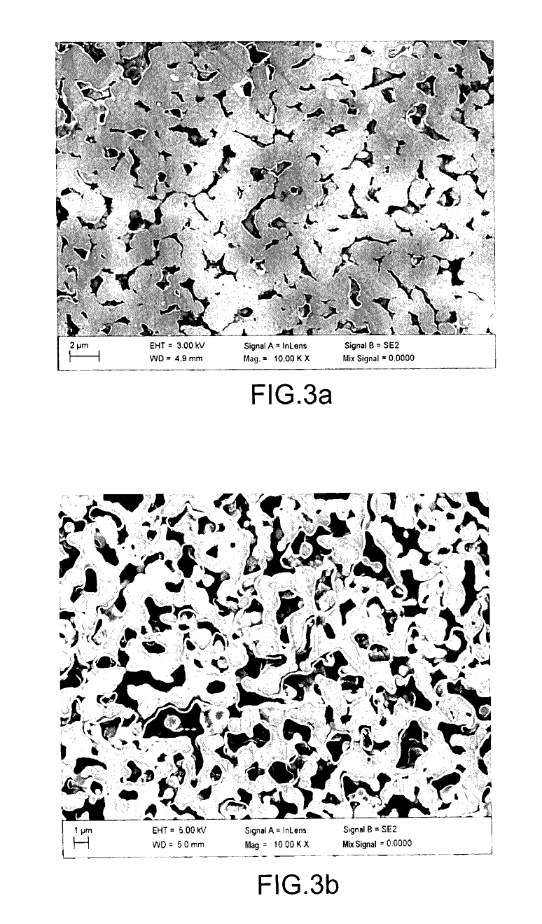

FIGS. 3a to 3c illustrate exemplary porosities obtained using various sintering operations for obtaining elementary joints in an assembly of the invention;

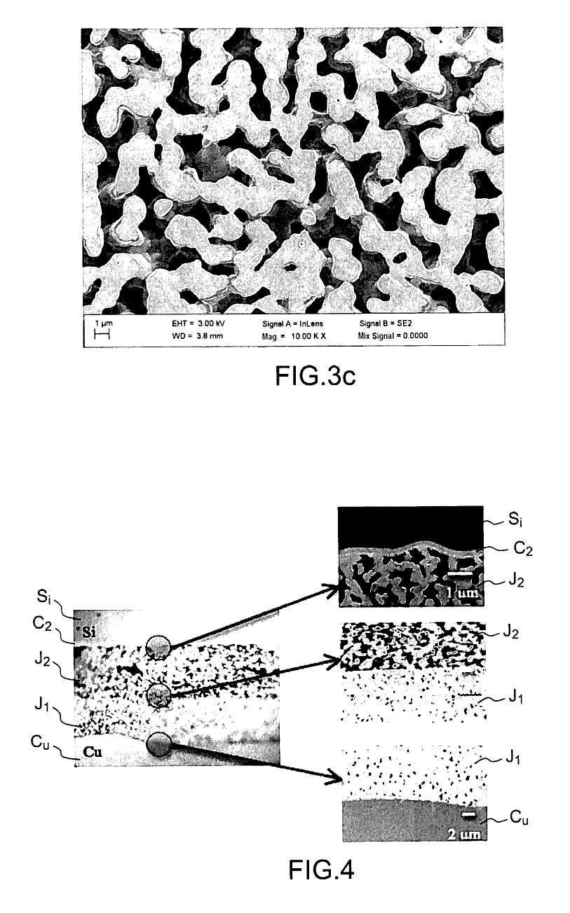

FIG. 4 illustrates a cross-sectional image of a proposed exemplary heterogeneous joint in an assembly according to the invention;

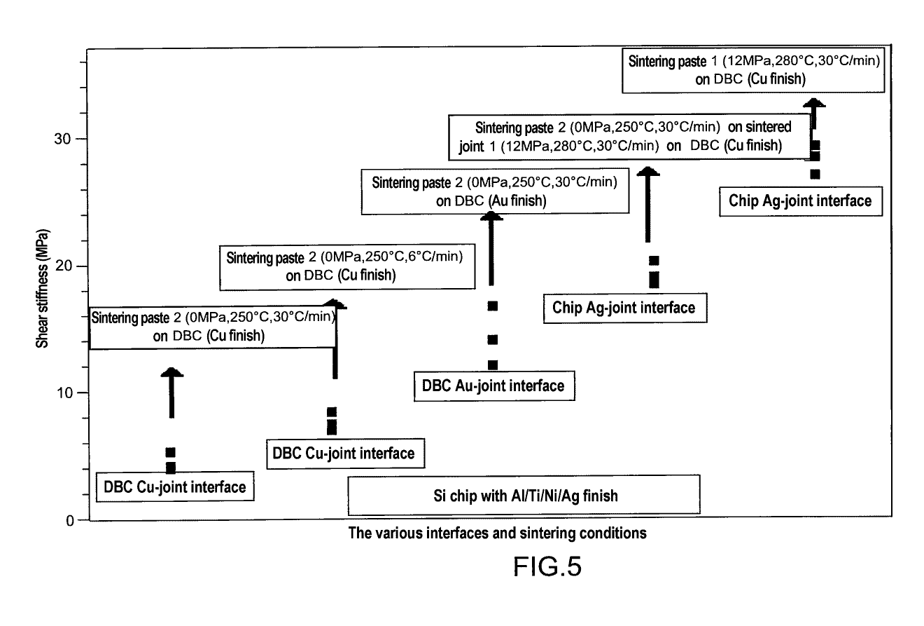

FIG. 5 illustrates the variation in the shear stiffness of an Si diode (Al/Ti/Ni/Ag finish) attached to a DBC with various finishes under various sintering conditions in the context of exemplary assemblies according to the invention; and

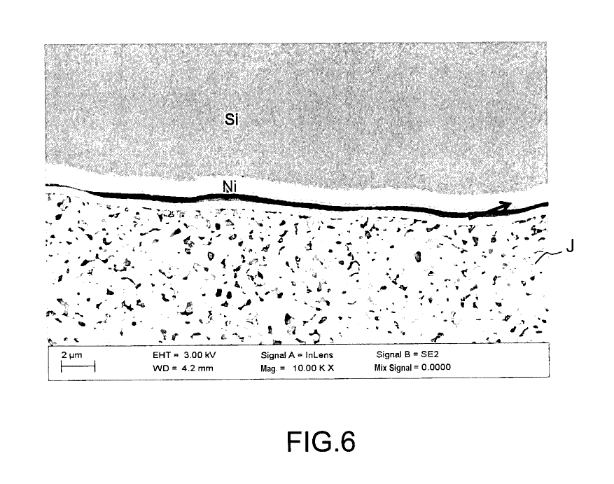

FIG. 6 shows an example of delamination of the Ag/Ni layer (generally used as the backside metallization of components) of an Si chip attached to a DBC with a Cu finish.

The present invention is particularly advantageous in the context of high-power-density and high-temperature (above 200° C.) applications and allows steps of metallization of direct bonded copper (DBC) and active metal brazing (AMB) type substrates, inter alia, with noble metals to be obviated, a good adhesion with substrates requiring a high pressure to be ensured and the thermomechanical reliability of the joint to be improved.

Active metal brazing (AMB) type substrates include a film or layer interposed between a ceramic substrate and a copper film. Increasing the temperature, generally of the entire assembly, up to the melting point of the “AMB” film without application of pressure causes via diffusion effects the AMB film to react on the one hand with the copper and on the other hand with the ceramic substrate.

Typically, the present invention makes it possible to produce electrical and/or mechanical interconnects that are able to function at temperatures above 300° C. with, during the active-component die-attach, very low pressures, typically lower than 100 g/cm² (or even no pressure) and process temperature profiles not exceeding 250° C., by using pastes containing metal nanoparticles. It also makes it possible to obtain joints each of which has nonuniform properties and to ensure a good mechanical adhesion to substrates when the application of pressure is necessary during sintering, without said pressure needing to be applied to the active components.

It firstly consists in producing with a high pressure a first sintered layer on the substrate (a high pressure being required to ensure a good mechanical adhesion) using a flat plate (of glass, aluminum, Teflon, Al₂O₃ etc.) that does not adhere to the sintered joint. The plate is then removed after this first step. The same step may be repeated a number of times under different sintering conditions to obtain various joint densities (lower pressures and/or temperatures obtain a less dense joint). As this step is carried out in the absence of semiconductors, pastes containing micron-sized particles may be used with high-pressure and high-temperature sintering processes.

A paste with nanosize particles is then deposited on the already sintered joint. The semiconductor is then placed on the paste and a modest pressure (possibly as low as 100 g/cm²) is applied to ensure a good contact between the paste and the metallization of the chip.

A temperature cycle allowing the paste of nanoparticles to be sintered is then applied. At the end of the process, an electrical and mechanical interconnect is ensured between the semiconductor and the substrate.

The density of the joint in the last step may also be controlled by the process even without varying the pressure. This interconnect technique has the following advantages:
all the conventional advantages of sintered joints (a good thermal and electrical conductivity, and operating temperature higher than the process temperature, etc.);
low pressures or no pressure may be applied to sensitive components, allowing a plurality of components with different thicknesses to be attached, while nonetheless ensuring a good adhesion to substrates requiring high pressures (Cu, Ni, polymers, etc.);
it allows the density of the various layers in a given joint to be controlled, allowing elastic modulus to be controlled and joints to be created with layers able to absorb thermomechanical strains and relax stress at critical points (the metallization of the chip for example) thus allowing a better reliability under thermal cycling.

It will be noted that the sintering process may be carried out by conduction from hotplates. Other techniques such as heating by microwave or by laser may also be employed.

### EXEMPLARY ASSEMBLY ACCORDING TO THE INVENTION

A silicon diode with an Al/Ti/Ni/Ag finish is attached to a DBC with no particular noble-metal finish (Cu finish) using a plurality of sintering steps.

It will be noted that in the case of a substrate with a finishing layer made of Cu, a deoxidizing step is carried out with formic acid just before the deposition of the paste.

### First Exemplary Process for Manufacturing an Assembly According to the Invention

The process used to produce this assembly is illustrated in FIGS. 2a to 2c.

Step 1:

A first layer of silver paste (paste P1) compatible with copper finishing layers is deposited on the first element E1 constituted by the DBC (layer of Al₂O₃ between two layers of Cu) by screen printing. The silver paste may typically comprise a dispersant, a binder, a solvent and silver nanoparticles. A step of drying the paste is carried out at 130° C. for 30 minutes.

The sintering operation is then carried out while applying a glass plate (the intermediate part Ei) to the dried paste with a pressure of 12 MPa at a temperature of 280° C. for 200 seconds, as illustrated in FIG. 2a, to form the first elementary joint J1, the heat source being referenced S_{ch}. These conditions make it possible to obtain a good adhesion between the joint and the Cu layer with a shear stiffness of 28 MPa (measured by attaching an Si chip of Ag finish). It will be noted that in trials carried out at pressures of 9 MPa and 6 MPa the Applicant observed decreases in shear stiffness of 50% and 80%.

Under a pressure of 3 MPa, the shear stiffness decreases to almost zero.

In the manufacture of the proposed structure, the glass plate Ei easily detaches from the first elementary joint thus formed and of first density.

### Step 2:

A second layer of a paste P2 containing silver nanoparticles and compatible with Ag and Au finishes is deposited by screen printing on the first sintered elementary joint (sintered joint J1), as illustrated in FIG. 2b.

The Si chip (Ag finish), i.e. the element E1 with a finishing layer C2, is then placed on the Ag paste and a sintering cycle at a temperature of 250° C. with a very low pressure (typically lower than 0.1 MPa) is carried out (the heat source being referenced Sch). The modest pressure applied ensures a good contact between the paste and the chip.

The density of this layer may be controlled by the ramp of the temperature increase as shown by the SEM micrographs in FIGS. 3a, 3b and 3c, taken after ramps of 6, 15 and 30 ° C./min, respectively.

The decrease in joint density and increase in the size and number of the pores observed in the joint as the gradient of the temperature ramp-up is increased are initially related to the evaporation of the solvent, binder and dispersant (used to form the paste) during the sintering. Under very rapid temperature ramp-ups volatile products do not have time to escape from the joint before the start of the sintering and their evaporation during the process leads to the creation of many large pores.

FIG. 2c illustrates the assembly thus produced, comprising a heterogeneous joint resulting from the stack of the first elementary joint J1 and the second elementary joint J2 and allowing the elements E1 and E2 to be joined.

The effect of a plurality of parameters of the sintering and various finishing layers of the DBC on the shear rigidity of Si diodes having a Al/Ti/Ni/Ag finish have been studied.

For the paste P2 not requiring the use of pressure, average shear rigidities of 4.5 MPa and 13 MPa were obtained, for a finishing layer made of Cu and a finishing layer made of Au, respectively, with a sintering temperature of 250° C. for 20 minutes and a temperature ramp-up of 30° C./min. These sintering conditions lead to a joint density comparable to that shown in FIG. 3c.

Even when a process allowing a much higher joint density to be obtained was used (joint of comparable density to that shown in FIG. 3a), the shear stiffness on a DBC with a Cu finish was 6.5 MPa. This increase may be related to the much larger area of contact when the joint is denser. After the shear tests, delamination was observed on the Cu- and Au-side of the DBC indicating a better adhesion to the Ag metallization of the chip. In order to take advantage of the good adhesion of the sintered Ag joint to a finishing layer made of Ag, the structure shown in FIG. 4 was produced and subjected to shear testing. FIG. 4 shows a cross-sectional view, of a joint produced in two steps, showing the two layers of different densities associated with the first elementary joint J1 and with the second elementary joint J2 forming the final joint and joining the layer Cu of the DBC to the silicon diode Si, via the layer C2. This structure exhibited an average stiffness of 19 MPa when the same sintering conditions as those used with the Au and Cu finishing layers (250° C. and a ramp of 30° C./min) were used. After the shear testing, delamination was observed on the Ag-metallization-layer side of the chip. A high-pressure (12 MPa) sintering trial with the paste P1 on a Cu finishing layer gave the best shear stiffness with an average value of 28 MPa.

FIG. 5 shows the dependence of the mechanical stiffness of the chips on the material of the finishing layer and on the various aforementioned sintering conditions. In addition, for each set of conditions and as determined by shear testing, the interface having the lowest adhesion is indicated. For each set of conditions, three samples were tested in order to obtain an acceptable statistic and are illustrated by the three black squares shown in FIG. 5.

Obviously, the decrease in joint density induces a decrease in the thermal and electrical conductivity of the attach of the chip. For example according to U.S. Pat. No. 8,257,795 B2, a decrease in the relative density of the joint from 80% to 57% induces a decrease in electrical conductivity from 4.2×10⁵ to 2.6×10⁵ (Ω·cm)⁻¹ and in thermal conductivity from 78 to 30 W/m.K. The lowest values are about the same as those of the conventional solders presented in the following table.

| | Au88Ge12 | Pb95.5Sn2Ag2.5 | Au80Sn20 |
|---|---|---|---|
| Electrical conductivity | 0.2 × 10⁴ | 0.35 × 10⁵ | 0.6 × 10⁵ |
| (Ω · cm)⁻¹ | | | |
| Thermal conductivity | 44 | 23 | 58 |
| W/m · K | | | |

On the basis of these results, the Applicant was able to conclude that advantageous electrical or mechanical properties are obtained for relative joint densities of as low as 50%.

It will be noted that the joining process with the paste 1 at a pressure of 12 MPa makes it possible to obtain the best shear rigidity. However, this process is incompatible with components that are sensitive to high pressures and the joint is very dense (high Young's modulus) this possibly causing high strains to be generated in the semiconductor metallizations under thermal cycling (difference in TEC between Si and the DBC). FIG. 6 shows an example of delamination of the Ag/Ni layer (generally used as the backside metallization of components) of an Si chip attached to a DBC with a Cu finish after 700 thermal cycles between −40° C. and 160° C. when a dense joint J (joint 1 in FIG. 4) is used. After the 700 cycles, shear rigidity had decreased from 28 MPa to 10 MPa and a delamination from 60% of the initial area was observed by scanning acoustic microscopy (SAM). This thermomechanical reliability problem may be retarded or even prevented if the improved structure of the present invention is used, this structure allowing a joint of relatively low density to be obtained in contact with the semiconductor. This induces a lower Young's modulus and therefore a better absorption of thermomechanical strains, leading to a better joint reliability.

### Second Exemplary Process for Manufacturing an Assembly According to the Invention

### Step 1:

The first step comprises:
screen printing sintering paste on the substrate using a mask of 200 μm thickness;
drying the sintering paste (30 minutes at 130° C.) leading to a loss of volume and to a thickness of 150 μm;
sintering the sintering paste under high pressure applied with a glass plate (12 MPa, 275 seconds at 280° C.) so as to form the first elementary joint, leading to a thickness of 60 μm.

### Step 2:

A pressure-sintering paste is used for the second deposition (such a paste is generally less expensive and more easily depositable by screen printing) while pressing lightly on the chip.

However, this type of pressure-sintering paste needs to be dried to remove organic binders, this not being the case for pressureless sintering pastes. This drying step, when it is followed by a low-pressure joining process, is mechanically weak at the joint/chip interface (the zone of rupture).

The solution proposed in this second variant is to deposit a very thin layer of this type of sintering paste on the first elementary joint so as to make it possible to skip the drying and thereby improve the joint/chip interface, which is more robust when the paste is not dried. The following elementary steps are carried out:
sintering paste is screen printed on the first elementary joint with a mask of 70 μm thickness. When the first elementary joint is sintered, it densifies, and its final thickness after sintering is 60 μm, thereby allowing a deposit of 10 μm using a screen of 70 μm thickness;
the chip is deposited on the preformed assembly then the chip is sintered on the undried paste of small thickness under low pressure (3 MPa, 275 s at 280° C.).

Thus wettability is improved as a non-dried paste is used.

The advantages of this second exemplary process especially result from:
the use of a single type of (pressure) sintering paste that is less expensive and more easily processable;
the screen printing of a small thickness of paste using a screen of standard thickness. This small thickness allows the binders to be removed without problems during the joining process, and therefore makes it possible to skip the drying step;
the better adhesion obtained between the joint and chip (which is often a weak point) even at low pressure levels (<9 MPa).

1. An assembly comprising a first element having a first thermal expansion coefficient, a second element having a second thermal expansion coefficient and at least one joint connecting said first element and said second element, wherein said joint is heterogeneous and includes a stack of at least one first elementary joint of first density and of a second elementary joint of second density, said first and second densities being different.

2. The assembly according to claim 1, wherein one of the elements comprises a semiconductor component, possibly a silicon diode.

3. The assembly according to claim 1, wherein said heterogeneous joint is metallic.

4. The assembly according to claim 1, wherein the first element and/or the second element have/has a metallic surface to be joined and attached to said joint.

5. The assembly according to claim 1, wherein at least one of the two elements is a ceramic substrate possibly made of Al₂O₃ or of Si₃N₄ or of AlN and possibly including at least one metallic layer on one of its faces.

6. The assembly according to claim 1, wherein the first element and the second element comprise a finishing layer intended to make contact with one of the elementary joints.

7. The assembly according to claim 6, wherein the thickness of the finishing layer is of the order of one nanometer or one micron.

8. The assembly according to claim 1, wherein at least one of the first and/or second elements have/has a surface made of copper, possibly a finishing layer.

9. The assembly according to claim 1, wherein the first elementary joint and/or the second elementary joint include/includes nanoparticles.

10. The assembly according to claim 1, wherein the first elementary joint includes microparticles, the second elementary joint including nanoparticles.

11. The assembly according to claim 1, wherein the first elementary joint and/or the second elementary joint are/is based on silver or copper or gold or silver and copper.

12. The assembly according to claim 1, wherein the first density is about 90% with respect to the bulk metal, which is possibly silver, the second density being about 60% relative to the bulk metal, which is possibly silver.

13. A process for manufacturing an assembly comprising a joint of heterogeneous density and two elements of different thermal expansion coefficients, comprising the following steps:
depositing a first paste or a first film on the surface of the first element;
a first sintering operation under first temperature and pressure conditions so as to produce a first elementary joint of first density;
depositing a second paste or a second film on the surface of said first elementary joint;
a second sintering operation under second temperature and pressure conditions so as to define a second elementary joint of second density different from said first density on the surface of the first elementary joint in order to form said heterogeneous joint;
applying the second element.

14. The process for manufacturing an assembly according to claim 13, wherein the first and/or second paste are/is metallic or the first film and/or the second film are/is metallic.

15. The process for manufacturing an assembly comprising a heterogeneous joint as claimed in claim 13, wherein the second sintering operation is carried out under lower temperature and/or lower pressure conditions than those of the first sintering operation.

16. The process for manufacturing an assembly comprising a heterogeneous joint according to claim 13, wherein the first sintering operation is carried out while applying an intermediate part to said deposited first paste or to said first film, said part possibly being a glass plate or an element made of Teflon®, or an element made of ceramic, or an element made of aluminum, or an element made of diamond, or an element made of sapphire, or an element made of silicon, or an element made of silicon carbide.

17. The process for manufacturing an assembly comprising a heterogeneous joint according to claim 13, wherein the second sintering operation is carried out while applying the second element to the second paste or to the second film.

18. The process for manufacturing an assembly comprising a heterogeneous joint according to claim 13, comprising a step of drying said first paste and/or a step of drying said second paste.

19. The process for manufacturing an assembly comprising a heterogeneous joint according to claim 13, wherein the first paste and/or the second paste are/is deposited by screen printing.

20. The process for manufacturing an assembly comprising a heterogeneous joint according to claim 13, wherein, the first element having a copper surface, the first paste is silver-based and the second paste is also silver-based.

21. The process for manufacturing an assembly comprising a heterogeneous joint according to claim 13, wherein the first and/or second paste comprise/comprises metal nanoparticles.

22. The process for manufacturing an assembly comprising a heterogeneous joint according to claim 13, wherein the first element is a substrate and the second element is a semiconductor chip.

23. The process for manufacturing an assembly comprising a heterogeneous joint according to claim 19, wherein the first and second pastes are deposited by screen printing with the same type of sintering paste, the thickness of the deposited first paste possibly being larger than the thickness of the deposited second paste.
